(19) United States
(12) Patent Application Publication
(10) Pub. No.: US 2008/0064605 A1
(43) Pub. Date: Mar. 13, 2008

(54) Manufacturing method of superconducting magnesium diboride thin film and superconducting magnesium diboride thin film

(75) Inventors: Hiroyuki Yamamoto, Kokubunji (JP); Akira Tsukamoto, Toda (JP); Haruhiro Hasegawa, Kokubunji (JP); Kazuo Saitoh, Kodaira (JP)

Correspondence Address: Stanley P. Fisher;Reed Smith LLP, Suite 1400, 3110 Fairview Park Drive, Falls Church, VA, 22042-4503, US

(73) Assignee: Hitachi, Ltd.

(21) Appl. No.: 11/798,021

(22) Filed: May 9, 2007

(30) Foreign Application Priority Data
May 24, 2006 (JP) 2006-143472

(51) Int. Cl. H01L 39/24

(52) U.S. Cl. 505/100; 505/470; 427/62

(57) ABSTRACT

A superconducting magnesium diboride (MgB₂) thin film showing a high critical current density to an angle of an applied magnetic field for a wide range is provided. Columnar crystal grains of MgB₂ grow with the same tilted to the normal line of the substrate by supplying a magnesium (Mg) flux and a boron (B) flux from direction tilted each to the normal axis of a substrate in high vacuum. The superconducting magnesium diboride (MgB₂) thin film comprising a plurality of layers containing MgB₂ columnar crystal grains with the angle of the grain boundaries being different from each other is formed by controlling the angle of supplying the magnesium (Mg) flux and the boron (B) flux to the substrate.

### CLAIM OF PRIORITY

The present application claims priority from Japanese application JP 2006-143472 filed on May 24, 2006, the content of which is hereby incorporated by reference into this application.

### BACKGROUND OF THE INVENTION

1. Field of the Invention

The present invention relates to a structure and a manufacturing method of a superconducting magnesium diboride (MgB₂) thin film applicable to a superconducting device that operates in a magnetic field such as a probe coil for use in nuclear magnetic resistance (NMR) measurement.

2. Description of the Related Art

For superconducting devices operating in magnetic fields such as a probe coil for use in nuclear magnetic resonance (MNR) measurement using superconducting materials, a superconducting thin film showing high critical current density in magnetic fields has been demanded. Generally, the critical current density of the superconducting thin film lowers along with increase in the magnetic field intensity and, further, also depends on the angle of the magnetic field to be applied. Further, the superconductor has a property of perfect diamagnetism and has a magnetization ratio as high as −¼π. Accordingly, on the design of a probe coil, it is necessary to keep the uniformity of a static magnetic field so as not to disturb the uniform magnetic field.

For this purpose, it has been devised to dispose a superconducting thin film of a superconducting device in parallel with the static magnetic field so as not to disturb the uniform magnetic field. On the other hand, it has pointed that a structure in which a superconductive thin film is disposed in parallel with the uniform magnetic field is disadvantageous, since an assembly of substrates forming the superconductive thin film tends to disturb the uniform magnetic field. In view of the above, it has been studied to adopt a Bobbin type probe coil to avoid the problem. In the probe coil of this type, since the superconducting thin film undergoes a magnetic field in the direction of normal line, it is necessary that a superconducting thin film show a high critical current density to the magnetic field.

It has been known that the critical current density in the magnetic field of a superconducting magnesium diboride (MgB₂) thin film has a strong correlation with the crystal structure of the thin film (Non-Patent Document 1: written by H. Kitaguchi et al, “MgB₂ films with very high critical current densities due to strong grain boundary pinning”, Applied Physics Letters, Vol. 85, No. 14, pp. 2842-2844 (2004)). When magnesium (Mg) and boron (B) are evaporated simultaneously on a substrate under high vacuum using predetermined conditions, an MgB₂ thin film containing columnar crystal grains which grow in the direction perpendicular to the substrate is formed.

The grain boundaries of the columnar crystal grains act as effective pinning centers in the magnetic field. That is, a high critical current density is obtained in the case of applying a magnetic field in the direction parallel to the grain boundaries of the columnar crystal grains. Since the columnar grains in the MgB₂ thin film grow in the direction substantially perpendicular to the plane of the substrate, a high critical current density is obtained in the case of applying a magnetic field in the direction substantially perpendicular to the substrate plane. However, as the angle of the applied magnetic field is displaced from the direction perpendicular to the substrate plane (growing direction of the columnar crystal grain), the pinning force due to the crystal grain boundary is weakened and the critical current density decreases. Accordingly, existent MgB₂ thin films involve a problem that the range of the angle of applied magnetic field capable of obtaining a high critical current density due to the grain boundary pinning of the columnar crystal grain is narrow.

### SUMMARY OF THE INVENTION

The present invention intends to provide a superconducting magnesium diboride (MgB₂) thin film showing a high critical current density to an angle of an applied magnetic field for a wide range in the case of undergoing a magnetic field from the direction of a normal line to the surface of a superconducting thin film.

A superconducting MgB₂ thin film according to the invention has a layer containing columnar crystal grains of MgB₂ by at least two layers in which grain boundaries of the columnar crystal grains in each of the layers are formed at angles different from each other. When an MgB₂ thin film is formed on a substrate under a predetermined conditions, for example, by evaporation or sputtering in ultra high vacuum, columnar crystal grains of MgB₂ are formed in the thin film. The growing angle of the columnar crystal grains has a correlation with a direction of supplying magnesium (Mg) and boron (B) fluxes to the substrate. The columnar crystal grains of MgB₂ grow along the direction of supplying magnesium (Mg) and boron (B) fluxes. Accordingly, when magnesium (Mg) and boron (B) fluxes are supplied to the substrate always in the same direction with no rotation of the substrate during film deposition, columnar crystal grains tilted in the supplying direction of the fluxes can be formed. By using the film deposition method, an MgB₂ thin film layer having columnar crystal grains tilted to the direction of a normal line to the substrate are stacked in plurality while changing the direction of tilting.

In the thin film of the structure described above, a strong pining force exerts at an angle of the applied magnetic field associated with the tilt angle of the columnar crystal grains in each of the layers. Accordingly, a plurality of critical current density peaks are obtained in the dependence of the critical current density on the angle of the applied magnetic field. As a result of superposing the plural critical current density peaks, a high critical current density can be obtained for the angle of applied magnetic field in a wide range.

According to the invention, a high critical current density is obtained to the angle of applied magnetic field in a wider range than usual in a superconducting magnesium diboride (MgB₂) thin film.

### BRIEF DESCRIPTION OF THE DRAWINGS

FIG. 1 is a view schematically showing a cross sectional structure of a superconducting MgB₂ thin film of Example 1.

FIG. 2 is a view schematically showing a method of manufacturing a superconducting MgB₂ thin film of Example 1, in which FIG. 2A is a view schematically showing a first step of manufacturing a thin film, FIG. 2B is a view schematically showing a second step of manufacturing a thin film, and FIG. 2C is a view schematically showing a third step of manufacturing a thin film.

FIG. 3 is a view showing the dependence of a critical current density on the angle of the applied magnetic field at a temperature of 4.2 K of the superconducting MgB₂ thin film of Example 1.

FIG. 4 is a view schematically showing a cross sectional structure of a superconducting MgB₂ thin film of Example 2.

FIG. 5 is a view schematically showing a method of manufacturing a superconducting MgB₂ thin film of Example 2, in which FIG. 5A is a view schematically showing a first step of manufacturing a thin film, FIG. 5B is a view schematically showing a second step of manufacturing a thin film, and FIG. 5C is a view schematically showing a third step of manufacturing a thin film.

FIG. 6 is a view showing the dependence of a critical current density on the angle of the applied magnetic field (temperature 4.2 K, field intensity 5T) of the superconducting MgB₂ thin film of Example 2.

FIG. 7 is a view schematically showing a cross sectional structure of a superconducting MgB₂ thin film of Example 3.

FIG. 8 is a view schematically showing a method of manufacturing a superconducting MgB₂ thin film of Example 3, in which FIG. 8A is a view schematically showing a first step of thin film manufacture, FIG. 8B is a view schematically showing a second step of manufacturing a thin film, FIG. 8C is a view schematically showing a third step of manufacturing a thin film, FIG. 8D is a view schematically showing a fourth step of manufacturing a thin film, and FIG. 8E is a view schematically showing a fifth step of manufacturing a thin film.

### DETAILED DESCRIPTION OF THE PREFERRED EMBODIMENTS

### Example 1

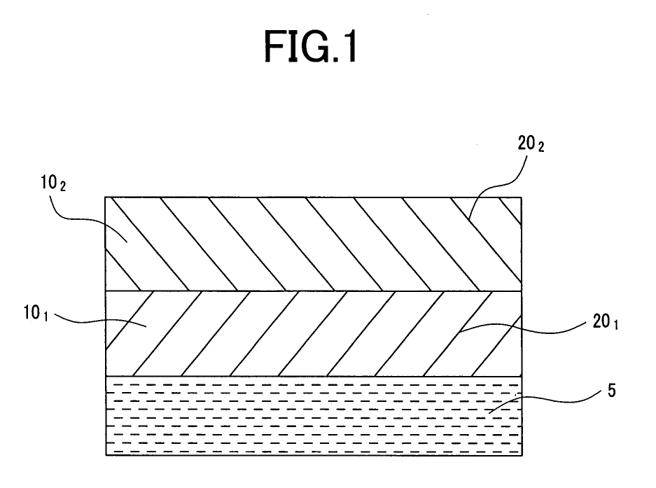

FIG. 1 shows a schematic cross sectional view of a superconducting MgB₂ thin film in Example 1. The supercoducting MgB₂ thin film of Example 1 comprises two layers of MgB₂ thin film 10₁ and 10₂ formed above a substrate 5. Columnar crystal grains are formed both in the first layer 10₁ and the second layer 10₂ of the MgB₂ thin film. The columnar crystal grains in each of the layers grow with their respective axis tilted in the direction of a normal line to the substrate 5. Moreover, tilt angles of the grain boundaries 20₁, 20₂ of the columnar crystal grains in the first layer 10₁ and the second layer 10₂ are different from each other. The film thickness is 300 nm for each of the layers.

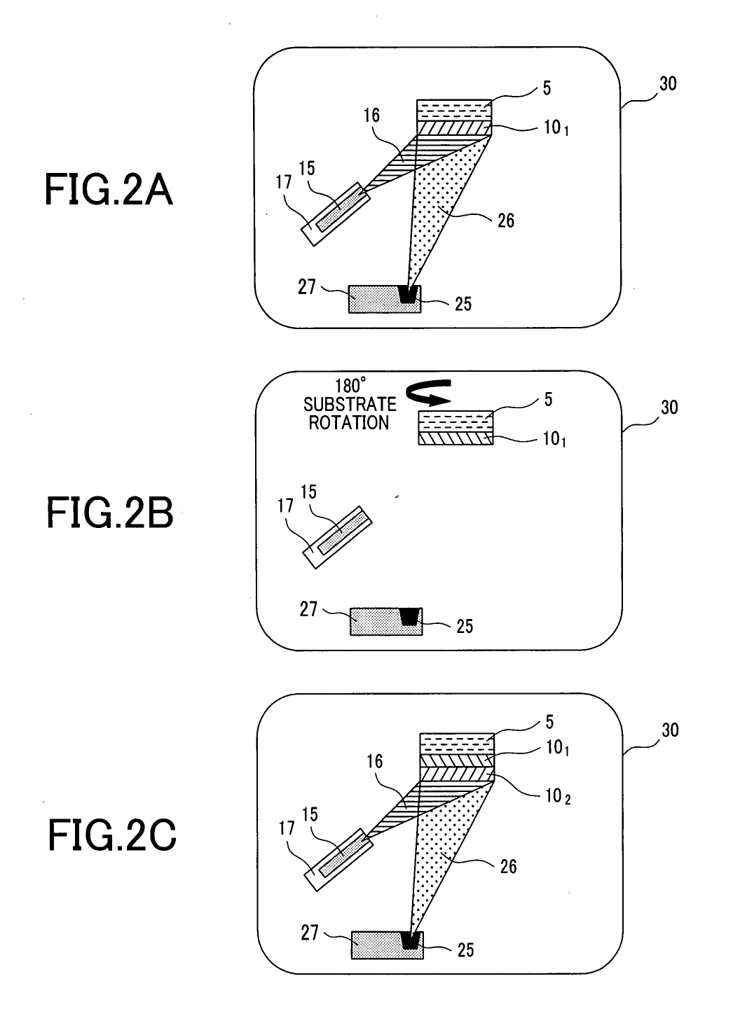

A method of manufacturing the superconducting MgB₂ thin film in Example 1 is to be described. FIGS. 2A, 2B, and 2C are views schematically showing the film deposition method for the superconducting MgB₂ thin film. FIG. 2A shows a first step of film deposition, FIG. 2B shows a second step of film deposition, and FIG. 2C shows a third step of film deposition.

The invention can be practiced by a general film deposition apparatus in which an effusion cell 17 and an electron beam evaporator 27 are disposed at positions displaced from the direction just below the substrate 5 on which deposition is to be conducted, and a magnesium (Mg) flux 16 and a boron (B) flux 26 are supplied each from a direction oblique to the normal line to the substrate.

At first, magnesium (Mg) 15 and boron (B) 25 are simultaneously evaporated on the surface of the substrate 5 in a vacuum chamber 30 under ultra high vacuum to form a first layer of an MgB₂ thin film 10₁. For the evaporation of magnesium (Mg), an effusion cell 17 for evaporating the starting material by resistance heating is used and an electron beam evaporator 27 is used for the evaporation of boron (B).

In Example 1, the magnesium (Mg) flux 16 is supplied at an angle tilted by about 45° from the normal line axis to the surface of the substrate, and the boron (B) flux 26 is supplied at an angle tilted by about 15° from the normal line axis to the surface of the substrate. The magnesium (Mg) flux 16 and the boron (B) flux 26 are supplied to the surface of the substrate 5 always in the same direction by resting the substrate 5 stationary during deposition. As a result, columnar crystal grains MgB₂ grow with their respective axis tilted in the direction of supplying the magnesium (Mg) and boron (B) fluxes. As described above, a first layer of the superconducting MgB₂ thin film 10₁ having grain boundaries of the columnar crystal grains tilted to the direction of the normal line of the surface of the substrate is formed.

After forming the first layer of the thin film 10₁, as shown in FIG. 2B, the substrate 5 is rotated by 180° to an in-plane direction. Then, as shown in FIG. 2C, a second layer of superconducting MgB₂ thin film 10₂ is stacked on the first layer 10₁ by the same deposition method as in the first layer. By the rotation of the substrate by 180°, the magnesium (Mg) flux 16 and the boron (B) flux 26 are supplied each from the direction symmetrical with the supplying direction of the magnesium (Mg) flux 16 and the boron (B) flux 26 of the first layer with respect to the normal line axis to the surface of the substrate, during deposition of the second layer. Accordingly, the grain boundaries of the columnar crystal grains in the second layer are formed with their respective axis tilted in symmetrical with the columnar crystal grains in the first layer with respect to the normal line axis to the surface of the substrate.

In the thin film forming process described above, the pressure was 1×10⁻⁸ to 1×10⁻⁷ Torr, the temperature of the substrate 5 was 300° C. and the evaporation rates for magnesium (Mg) and boron (B) were 14 Å/s and 0.8 Å/s, respectively, during film deposition.

The thus formed superconducting MgB₂ thin film of the multilayer structure is fabricated by way of photolithography and etching process into a bridge pattern of 0.2 mm width. The critical current density of a thin film specimen is measured in liquid helium (temperature: 4.2 K) while changing the angle of magnetic field to be applied to the prepared MgB₂ thin film specimen.

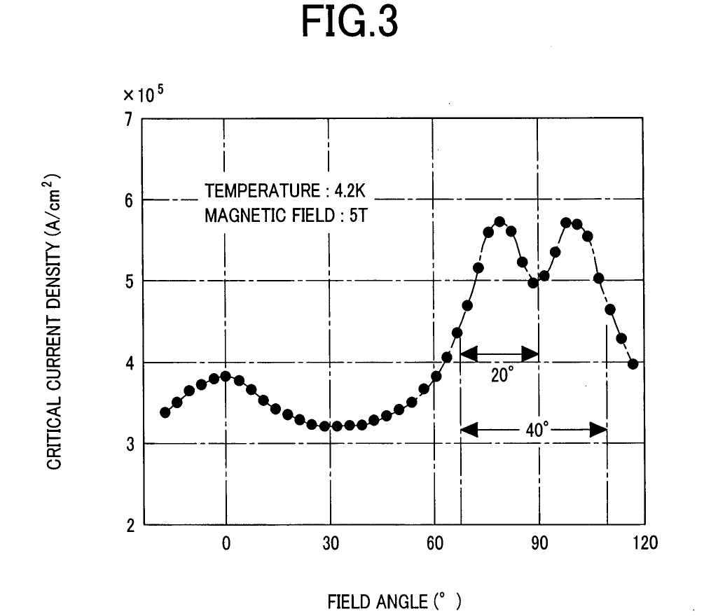

FIG. 3 is a view showing the dependence of the critical current density on the angle of applied magnetic field of the superconducting-MgB₂ thin film in Example 1 (temperature: 4.2 K, field intensity: 5T). From the graph, two critical current density peaks can be confirmed near the angle of applied magnetic field of 90° (direction perpendicular to the surface of the thin film). They are peaks associated with the grain boundary pinning of the columnar crystal grains of the respective first layer 10₁ and the second layer 10₂ in the thin film of multilayer structure. In the MgB₂ thin film having columnar crystal grains, the pinning force exerts most intensely in the case of applying a magnetic field in the direction identical with the grain boundaries 20₁ and 20₂ of the crystal grains, and high critical current density is obtained. Accordingly, in the dependence of the critical current density on the angle of the applied magnetic field, peaks of the critical current density appear at the tilt angle of the columnar crystal grains.

In the existent thin film of the single layered structure, only one peak of the critical current associated with the growing angle of the columnar crystal grains is confirmed. In this case, the range for the field angle capable of maintaining a value of 80% for the maximum value of the critical current density is about 20°. In contrast, since the MgB₂ thin film of Example 1 is formed of two layers of thin film in which the columnar crystal grains grow with their respective axis tilted by an angle in symmetrical with respect to the normal line axis to the surface of the substrate, peaks of the critical current density associated with the respective tilt angles (about 80°, about 110°) are obtained. As a result, the range of the field angle capable of maintaining the value of 80% for the maximum value of the critical current density is extended by about twice (40°) compared with that of the existent single layered MgB₂ thin film (20°).

Further, while materials such as Al₂O₃, LaAlO₃, LSAT, MgO, AlN, polyimide and polytetrafluoroethylene were used for the substrate 5, an identical result was obtained for any of the substrates. While the effusion cell was used for the evaporation of magnesium (Mg) in Example 1, it is apparent that a thin film having the same structure as in Example 1 can be formed also in the case of conducting thin film formation by evaporating magnesium (Mg) using the electron beam evaporator.

### Example 2

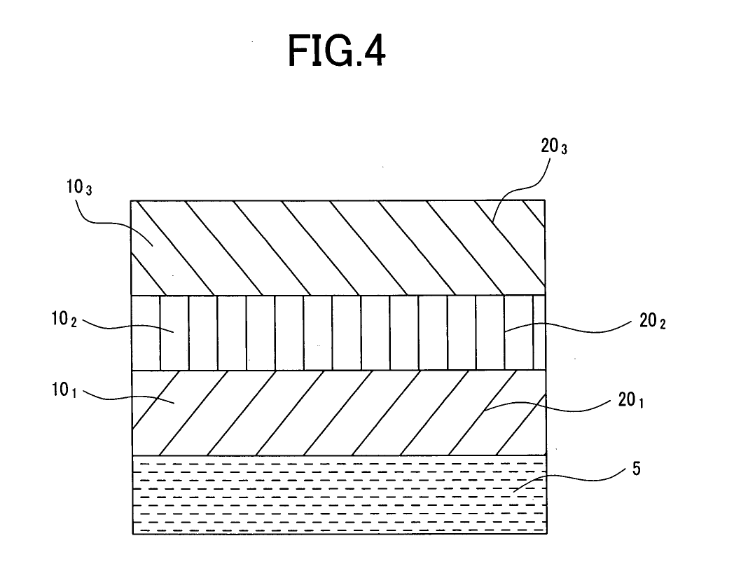

FIG. 4 shows a schematic cross sectional structure of a superconducting MgB₂ thin film of Example 2. The MgB₂ thin film in Example 2 comprises three layers each containing MgB₂ columnar crystal grains which grow at an angle different from each other. A first layer 10₁ and a third layer 10₃ contain columnar crystal grains that grow with their respective axis tilted each by an angle symmetrical with each other with respect to the direction of a normal line to the substrate. A second layer 10₂ put between the two layers contains columnar crystal grains which grow in parallel with the direction of a normal line to the substrate. The film thickness is 300 nm for each of the layers.

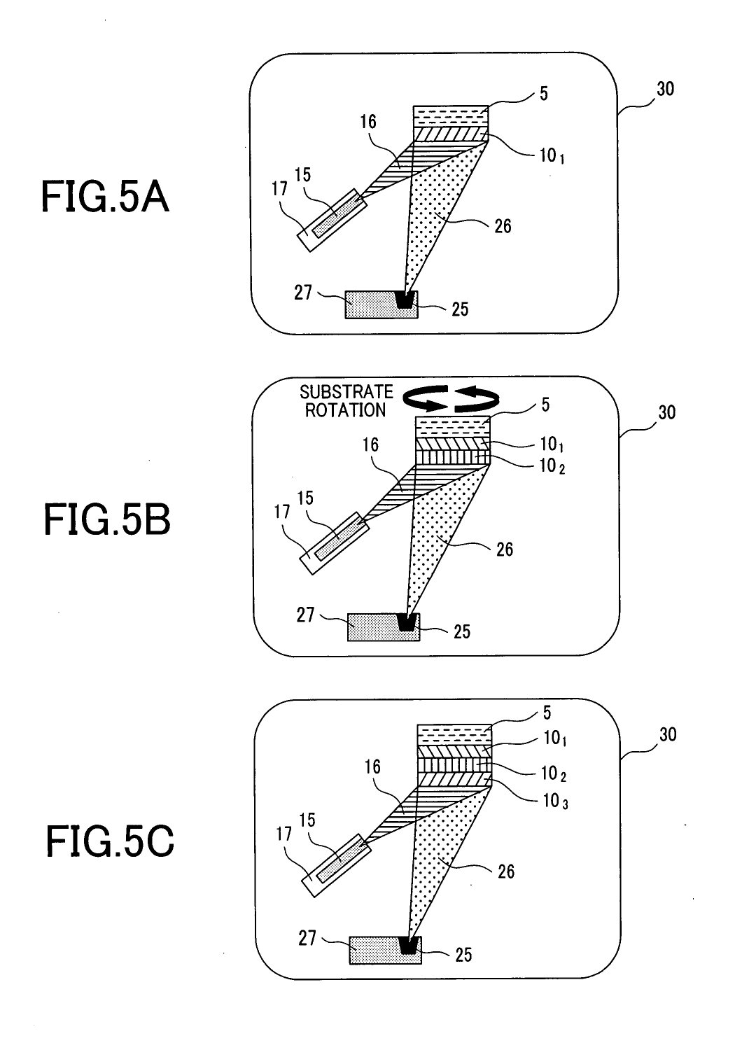

A method of manufacturing the superconducting MgB₂ thin film in Example 2 is to be described. FIGS. 5A, 5B, and 5C are views schematically showing the method of depositing the superconducting MgB₂ thin film. FIG. 5A shows a first step of the film deposition, FIG. 5B shows a second step of film deposition, and FIG. 5C shows a third step of film deposition. Also in Example 2, the film deposition apparatus may be identical with that in Example 1, in which an effusion cell 17 and an electron beam evaporator 27 are disposed at positions displaced from the direction just below a substrate 5 on which deposition is to be conducted. A magnesium (Mg) flux 16 and a boron (B) flux 26 are supplied from a direction oblique to a normal line to the substrate 5.

At first, magnesium (Mg) and boron (B) are evaporated simultaneously above the substrate 5 in a vacuum chamber 30 under a ultra high vacuum to form a first layer of MgB₂ thin film 10₁. Magnesium (Mg) 15 is evaporated by an effusion cell 17 and an electron beam evaporator 27 is used for the evaporation of boron (B) 25. A magnesium (Mg) flux 16 is supplied at an angle tiled by about 45° from the axis of a normal line to the substrate, and a boron (B) flux 26 is supplied at an angle tilted by about 15° from the axis of the normal line to the substrate. The magnesium (Mg) flux 16 and the boron (B) flux 26 are supplied to the surface of the substrate 5 always in the same direction by resting the substrate 5 stationary during deposition. As a result, columnar crystal grains of MgB₂ grow with their respective axis tilted in the direction of supplying the magnesium (Mg) flux 16 and the boron (B) flux 26. As a result a first layer of the superconducting MgB₂ thin film 10₁ having grain boundaries of the columnar crystal grains tilted to the direction of the normal line of the surface of the substrate is formed in the same manner as in Example 1.

After forming the first layer of thin film 10₁, a second layer of thin film 10₂ was stacked above the first layer 10₁ as shown in FIG. 5B by the same film deposition method as in the first layer. However, in this step, film deposition was conducted while rotating the substrate 5 in an in-plane direction. Thus, the directions of supplying the magnesium (Mg) flux 16 and the boron (B) flux 26 to the surface of the substrate 5 are isometrical and the columnar crystal grains of MgB₂ grow in parallel without their respective axis tilted to the direction of the normal line of the surface of the substrate 5.

After forming the second layer of thin film 10₂, the substrate 5 is rotated by 180° in the in-plane direction such that the magnesium (Mg) flux 16 and the boron (B) flux 26 are supplied each in the opposite direction upon formation of the first layer thin film 10₁ to the normal line of the substrate. Then, as shown in FIG. 5C, a third layer of thin film 10₃ was stacked above the second layer 10₂ while resting the substrate stationary by the same film deposition method as in the first layer. As a result, a third layer of thin film 10₃ containing columnar crystal grains tilted in symmetrical with the columnar crystal grains in the first layer is formed with respect to the direction of the normal line of the surface of the substrate 5 in the same manner as in Example 1.

In the thin film forming process described above, the pressure was 1×10⁻⁸ to 1×10⁻⁷ Torr, the temperature of the substrate 5 was 300° C. and the evaporation rates for magnesium (Mg) and boron (B) were 14 Å/s and 0.8 Å/s, respectively, during film deposition.

The thus formed superconducting MgB₂ thin film of the multilayer structure was fabricated by way of photolithography and etching process into a bridge pattern of 0.2 mm width. The critical current density of a thin film specimen was measured in liquid helium (temperature: 4.2 K) while changing the angle of magnetic field applied to the prepared MgB₂ thin film specimen.

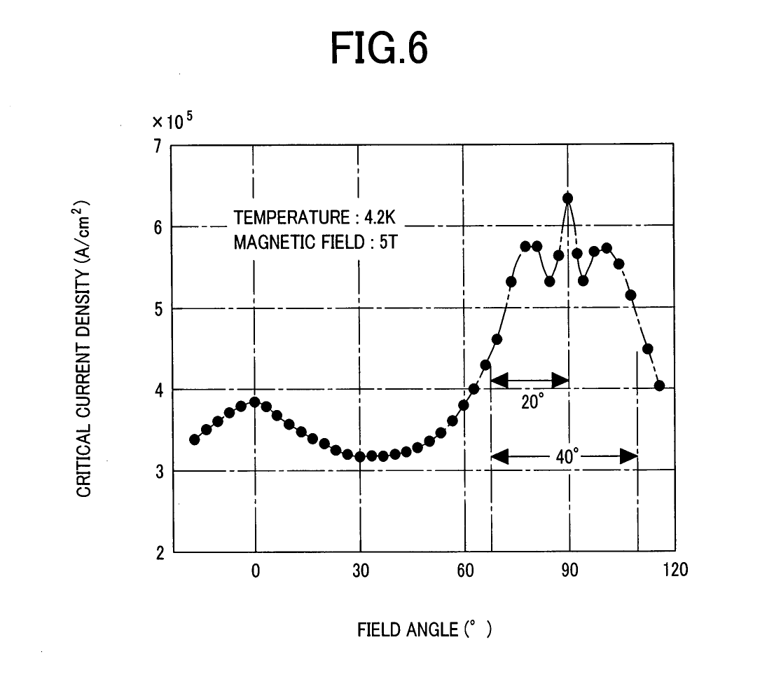

FIG. 6 is a view showing the dependence of the critical current density of the superconducting MgB₂ thin film on the angle of applied magnetic field in Example 2 (temperature: 4.2 K, field intensity: 5T). Since the MgB₂ thin film of Example 2 is formed of three layers of thin films in which growing angles of the columnar crystal grains are different, peaks of the critical current density associated with respective growing angles (about 80°, about 90°, about 110°) to the direction of the plane of the substrate are obtained. As a result, the range for the field angle capable of maintaining 80% value for the maximum value of the critical current density is extended by about twice (40°) compared with the existent mono-stacked MgB₂ thin film (20°). Further, a higher critical current density was observed for the direction of a normal line of the surface of the substrate 5.

Further, while materials such as Al₂O₃, LaAlO₃, LSAT, MgO, AlN, polylmide and polytetrafluoroethylene are used for the substrate 5, an identical result is obtained for any of the substrates. While the effusion cell is used for the evaporation of magnesium (Mg) in Example 2, it is apparent that a thin film having the same structure as in Example 2 can be formed also in the case of conducting thin film formation by evaporating magnesium (Mg) using the electron beam evaporator.

### Example 3

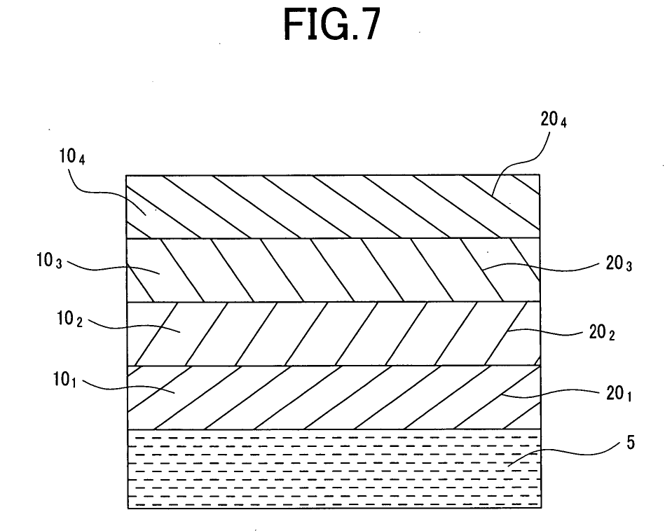

FIG. 7 shows a schematic cross sectional structure of a superconducting MgB₂ thin film of Example 3. MgB₂ thin film in Example 3 comprises four layers 10₁, 10₂, 10₃, and 10₄ containing MgB₂ columnar crystal grains that grow at angles different from each other.

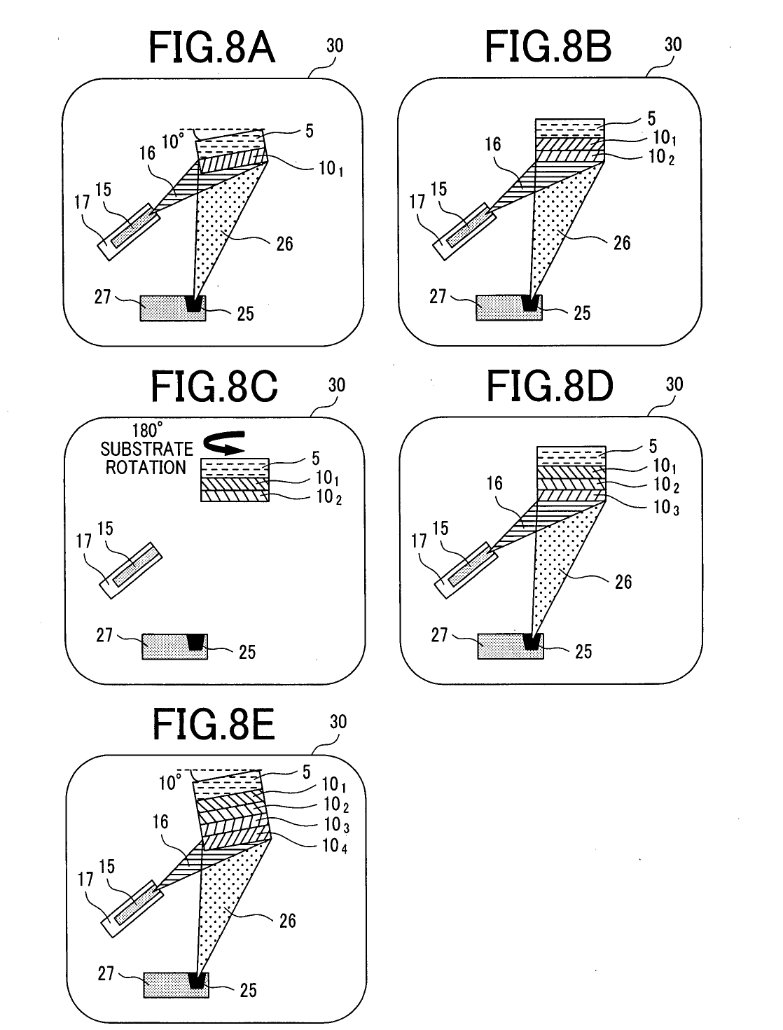

A method of manufacturing a superconducting MgB₂ thin film in Example 3 is to be described. FIGS. 8A, 8B, 8C, 8D, and 8E are views schematically showing the film deposition method of a superconducting MgB₂ thin film. FIG. 8A shows a first step of film deposition, FIG. 8B shows a second step of film deposition, FIG. 8C shows a third step of film deposition, FIG. 8D shows a fourth step of film deposition, and FIG. 8E shows a fifth step of film deposition. Also in Example 3, the film deposition apparatus may be identical with that in Example 1 in which an effusion cell 17 and an electron beam evaporator 27 are disposed at positions displaced from the direction just below a substrate 5, and a magnesium (Mg) flux 16 and a boron (B) flux 26 are supplied from an oblique direction to the normal line of the substrate 5.

At first, a film deposition surface of a substrate 5 is fixed in a state tiled by about 10° from the horizontal direction as shown in FIG. 8A. In this state, magnesium (Mg) 15 and boron (B) 25 are evaporated simultaneously on the surface of the substrate 5 to form a first layer of MgB₂ thin film 10₁. Magnesium (Mg) 15 is evaporated by the effusion cell 17 and the electron beam evaporator 27 is used for the evaporation of boron (B) 25. In Example 3, the magnesium (Mg) flux 16 is supplied at an angle tiled by about 45° from the normal line axis to the surface of the substrate and the boron (B) flux 26 is supplied at an angle tilted by about 15° from the axis of the normal line to the substrate with the state before tilting the surface of the substrate from the horizontal direction being as a reference in Example 3. The magnesium (Mg) flux 16 and the boron (B) flux 26 are supplied to the substrate 5 always in the identical direction by not rotating the substrate during film deposition. As a result, the columnar crystal grains of MgB₂ grow with their respective axis tilted in the direction of supplying the magnesium (Mg) flux 16 and the boron (B) flux 26. As described above, the first layer of the superconducting MgB₂ thin film 10₁ having the grain boundary 20₁ of columnar crystal grains tilted by about 20° relative to the direction of the normal line to the substrate is formed.

After forming the first layer of thin film 10₁, the tilted substrate surface was returned and set in the horizontal direction. In this state, a second layer of thin film 10₂ is stacked over the first layer 10₁ by the same film deposition method as in the first layer as shown in FIG. 8B. As described above, the second layer of thin film 10₂ containing columnar crystal grains with less tilting to the direction of the normal line of the surface of the substrate (about 10°) than the first layer of thin film 10₁ is formed.

After forming the second layer of thin film 10₂, the substrate is rotated by 180° in the in-plane direction as shown in FIG. 8C. Then, while resting the substrate as it is, a third layer of a superconducting MgB₂ thin film 10₃ is stacked over the second layer 10₂ as shown in FIG. 8D by the same film deposition method as in the first and second layers. By rotating the substrate 180°, the magnesium (Mg) flux 16 and the boron (B) flux 26 are supplied each in the direction in symmetrical with the second layer in the direction of the normal line of the surface of the substrate during film deposition of the third layer. Accordingly, the grain boundaries 20₃ of the columnar crystal grains in the third layer are formed with their respective axis tilted in the direction symmetrical with the grain boundaries 20₂ of the columnar crystals of the second layer (about −10°) with reference to the direction of the normal line of the substrate.

Successively, in the same manner as in the formation of the first layer of thin film 10₁, the surface of the substrate is fixed in a state tilted by about 10° from the horizontal direction. In this state, a fourth layer of superconducting MgB₂ thin film 10₄ is stacked over the third layer 10₃ by the same film deposition method as in the first to third layers of thin films as shown in FIG. 8E. By tilting the surface of the substrate from the horizontal direction, a fourth layer of thin film 10₄ containing columnar crystal grains with larger tilting to the direction of the normal line of the substrate (about −20°) than the third layer of thin that of film 10₃ is formed.

In the thin film forming process described above, the pressure was 1×10⁻⁸ to 1×10⁻⁷ Torr, the temperature of the substrate 5 was 300° C. and the evaporation rates for magnesium (Mg) and boron (B) were 14 Å/s and 0.8 Å/s, respectively, during film deposition.

The thus formed superconducting MgB₂ thin film of the multilayer structure is fabricated by way of photolithography and etching process into a bridge pattern of 0.2 mm width. The critical current density of a thin film specimen is measured in liquid helium (temperature: 4.2 K) while changing the angle of magnetic field applied to the prepared MgB₂ thin film specimen. Since the MgB₂ thin film of Example 3 is formed of four layers of thin films of different growing angles of the columnar crystal grains, peaks of the critical current density associated with the growing angles of the columnar crystal grains (about 70°, about 80°, about 110°, and about 120°) in each of the layer relative to the direction of the substrate plane are obtained. As a result, the range for the field angle capable of maintaining the 80% value for the maximum value of the critical current density is extended by about three times (60°) compared with that of the existent single layered MgB₂ thin film (20°).

While materials such as Al₂O₃, LaAlO₃, LSAT, MgO, AlN, polyimide and polytetrafluoroethylene are used for the substrate 5, an identical result is obtained for any of the substrates. While the effusion cell is used for the evaporation of magnesium (Mg) in Example 3, it is apparent that a thin film having the same structure as in Example 3 can be formed also in the case of conducting thin film formation by evaporating magnesium (Mg) using the electron beam evaporator.

Description for the references in the drawings are as shown below.
5 . . . substrate,
10₁ . . . first layer of superconducting MgB₂ thin film,
10₂ . . . second layer of superconducting MgB₂ thin film,
10₃ . . . third layer of superconducting MgB₂ thin film,
10₄ . . . fourth layer of superconducting MgB₂ thin film,
20₁ . . . grain boundary of columnar crystal grains in the first layer of superconducting MgB₂ thin film,
20₂ . . . grain boundary of columnar crystal grains in the second layer of superconducting MgB₂ thin film,
20₃ . . . grain boundary of columnar crystal grains in the third layer of superconducting MgB₂ thin film,
20₄ . . . grain boundary of columnar crystal grains in the forth layer of superconducting MgB₂ thin film,
15 . . . magnesium (Mg) starting material,
16 . . . magnesium (Mg) flux,
17 . . . effusion cell,
25 . . . boron (B) starting material,
26 . . . boron (B) flux,
27 . . . electron beam evaporator,
30 . . . vacuum chamber.

What is claimed is:

1. A method of manufacturing a superconducting magnesium diboride thin film, comprising:
a step of locating a substrate such that a substrate surface is in a horizontal direction and directed downward in a ultra high vacuum chamber;
a first step of supplying a magnesium (Mg) flux and a boron (B) flux to the surface of the substrate from a magnesium (Mg) evaporator and a boron (B) evaporator disposed at positions tilted each by a predetermined angle in the direction of a normal line of the surface of the substrate relative to the surface of the substrate at positions below the surface of the substrate in the ultra high vacuum chamber;
a second step of supplying the magnesium (Mg) flux and the boron (B) flux to the surface of the substrate from positions different for the tilt angle in the first step to the direction of a normal line of the surface of the substrate at positions below the surface of the substrate relative to the surface of the substrate in the ultra high vacuum chamber; and
forming a multilayer structure in which columnar crystal grains of magnesium diboride grow at different angles in the direction opposite to each other to the direction of the normal line of the surface of the substrate between the first step and the second step to the surface of the substrate in the ultra high vacuum chamber.

2. A method of manufacturing a superconducting magnesium diboride thin film comprising:
a step of locating a substrate such that a substrate surface is in a horizontal direction and directed downward in a ultra high vacuum chamber;
a first step of supplying a magnesium (Mg) flux and a boron (B) flux to the surface of the substrate from a magnesium (Mg) evaporator and a boron (B) evaporator disposed at positions tilted each by a predetermined angle in the direction of a normal line of the surface of the substrate relative to the surface of the substrate at positions below the surface of the substrate in the ultra high vacuum chamber;
a second step of continuously rotating the substrate at the located position at a predetermined speed in the ultra high vacuum chamber, and supplying a magnesium (Mg) and a boron (B) flux to the surface of the substrate from the magnesium (Mg) evaporator and the boron (B) evaporator relative to the surface of the substrate;
a third step of supplying the magnesium (Mg) flux and the boron (B) flux to the surface of the substrate from the position different for the tilt angle in the first step to the surface of the substrate to the direction of the normal line of the surface of the substrate at positions below the surface of the substrate in the ultra high vacuum chamber;
wherein the columnar crystal grains of magnesium diboride grow on the surface of the substrate at different angles in the directions opposite to each other with respect to the direction of the normal line to the surface of the substrate between the first step and the third step in the ultra high vacuum chamber, and a multilayer structure where the columnar crystal grains grow in the direction of the normal line of the surface of the substrate is formed in the second step.

3. A method of manufacturing a superconducting magnesium diboride thin film according to claim 1, wherein
the first step is conducted repetitively at two angles different with respect to the direction of the normal line of the surface of the substrate, and
the second step is conducted repetitively at two angles different with respect to the direction of the normal line of the surface of the substrate.

4. A method of manufacturing a superconducting magnesium diboride thin film according to claim 1, wherein
the direction of supplying the magnesium (Mg) flux and the boron (B) flux to the surface of the substrate from angles tilted respectively relative to the direction of the normal line of the surface of the substrate in the first step and the second step to the surface of the substrate is changed by rotating the substrate within a plane by about 180° between the first step and the second step.

5. A method of manufacturing a superconducting magnesium diboride thin film according to claim 3, wherein
the direction of supplying the magnesium (Mg) flux and the boron (B) flux to the surface of the substrate from angles tilted respectively relative to the direction of the normal line of the surface of the substrate in the first step and the third step to the surface of the substrate is changed by rotating the substrate within a plane by about 180° between the first step and the third step.

6. A method of manufacturing a superconducting magnesium diboride thin film according to claim 2, wherein
the first step is conducted repetitively at two angles different with respect to the direction of the normal line of the surface of the substrate, and
the third step is conducted repetitively at two angles different with respect to the direction of the normal line of the surface of the substrate.

7. A method of manufacturing a superconducting magnesium diboride thin film according to claim 2, wherein
the direction of supplying the magnesium (Mg) flux and the boron (B) flux to the surface of the substrate from angles tilted respectively relative to the direction of the normal line of the surface of the substrate is changed in the first step and the third step to the surface of the substrate by rotating the substrate within a plane by about 180° between the first step and the third step.

8. A method of manufacturing a superconducting magnesium diboride thin film according to claim 6, wherein
the direction of supplying the magnesium (Mg) flux and the boron (B) flux to the surface of the substrate from angles tilted respectively relative to the direction of the normal line of the surface of the substrate is changed in the first step and the third step to the surface of the substrate by rotating the substrate within a plane by about 180° between the first step and the third step.

9. A method of manufacturing a superconducting magnesium diboride thin film according to claim 1, wherein
the magnesium (Mg) flux and the boron (B) flux in the first step and the second step are supplied by using a plurality of independent evaporators disposed in the ultra high vacuum chamber and put to temperature control independently.

10. A method of manufacturing a superconducting magnesium diboride thin film according to claim 2, wherein
the magnesium (Mg) flux and the boron (B) flux in the first step to the third steps are supplied by using a plurality of independent evaporators disposed in the ultra high vacuum chamber and put to temperature control independently.

11. A method of manufacturing a superconducting magnesium diboride thin film according to claim 1, wherein
the magnesium (Mg) flux is evaporated by a resistance heating evaporator and the boron (B) flux is evaporated by an electron beam evaporator in the first step and the second step.

12. A method of manufacturing a superconducting magnesium diboride thin film according to claim 2, wherein
the magnesium (Mg) flux is evaporated by a resistance heating evaporator and the boron (B) flux is evaporated by an electron beam evaporator in the first step to the third step.

13. A method of manufacturing a superconducting magnesium diboride thin film according to claim 1, wherein
both the magnesium (Mg) flux and the boron (B) flux are evaporated by an electron beam evaporator in the first step and the second step.

14. A method of manufacturing a superconducting magnesium diboride thin film according to claim 2, wherein
both the magnesium (Mg) flux and the boron (B) flux are evaporated by an electron beam evaporator in the first to the third steps.

15. A superconducting magnesium diboride thin film, comprising:
substrate;
a first superconducting thin film comprising magnesium diboride (MgB₂) of columnar crystal grains formed on the substrate at an angle tiled by a predetermined angle to the direction of a normal line of the surface of the substrate; and
a second superconducting thin film comprising magnesium diboride (MgB₂) of columnar crystal grains formed on the first superconducting thin film at an angle different from the angle relative to the normal line of the surface of the substrate.

16. A superconducting magnesium diboride thin film according to claim 15, wherein
a third superconducting thin film comprising magnesium diboride (MgB₂) of columnar crystal grains formed in the direction of the normal line of the surface of the substrate between the first superconducting thin film and the second superconducting thin film.

17. A superconducting magnesium diboride thin film according to claim 15, comprising:
a plurality of first superconducting thin films having different tilt angles in the direction of the predetermined angle, and
a plurality of second superconducting thin films having different tilt angles in the direction of the different angles.

18. A superconducting magnesium diboride thin film according to claim 16, comprising:
a plurality of first superconducting thin films having different tilt angles in the direction of the predetermined angle, and
a plurality of second superconducting thin films having different tilt angles in the direction of the different angles.
